(19) United States
(12) Patent Application Publication
(10) Pub. No.: US 2012/0118621 A1
(43) Pub. Date: May 17, 2012

(54) PRINTED CIRCUIT BOARD AND METHOD FOR MANUFACTURING THE SAME

(75) Inventors: Jin Won CHOI, Gyunggi-do (KR); Sung Won JEONG, Gyunggi-do (KR)

(73) Assignee: SAMSUNG ELECTRO-MECHANICS CO., LTD., Gyunggi-do (KR)

(21) Appl. No.: 13/091,045

(22) Filed: Apr. 20, 2011

(30) Foreign Application Priority Data
Nov. 17, 2010 (KR) 10-2010-0114567

(51) Int. Cl. H05K 1/02; H05K 1/11; H05K 3/00

(52) U.S. Cl. 174/258; 29/830; 174/267

(57) ABSTRACT

Disclosed herein is a printed circuit board, including: a base substrate having a connection pad; a lead pin bonded to the connection pad; and a surface treatment layer formed at the exposed portions of the connection pad and the lead pin.

### CROSS REFERENCE TO RELATED APPLICATION

This application claims the benefit of Korean Patent Application No. 10-2010-0114567, filed on Nov. 17, 2010, entitled “Printed Circuit Board And Method For Manufacturing The Same”, which is hereby incorporated by reference in its entirety into this application.

### BACKGROUND OF THE INVENTION

1. Technical Field

The present invention relates to a printed circuit board and a method of manufacturing the same.

2. Description of the Related Art

With the development of a semiconductor refinement technology, high integration, high speed, and low power consumption of LSI have progressed every year. In order to support the technology, the wiring density of the printed circuit board should be continuously increased. In the printed circuit board, the line width has been continuously refined, and thus, a flip-chip technology as a connection method has been prevalently used for several years in order to correspond to the increasing number of terminals of LSI.

A flip chip pin grid array (FCPGA) substrate is a substrate using a pin for connecting a printed circuit board and a main substrate.

FIGS. 5 to 10 are process flow charts schematically showing a method for manufacturing a printed circuit board according to the prior art.

First, as shown in FIG. 5, a base substrate 11 formed with a solder resist layer 12 having an opening that exposes a connection pad 13 is prepared. Thereafter, as shown in FIG. 6, surface treatment layers 15 and 17 are formed on the exposed connection pad 13 by using an electroless nickel immersion gold (ENIG) method, an electroless nickel immersion palladium immersion gold (ENPIG) method, or the like.

Next, as shown in FIG. 7, a solder paste 19 is printed on the formed surface treatment layers 15 and 17 and then, a lead pin 20 is disposed on the solder paste 19 as shown in FIG. 8.

In this configuration, the lead pin 20 is divided into a shaft portion 20a and a head portion 20b. It is preferable that the surface treatment layer is made of nickel 23 and gold 25 in order to secure mechanochemical reliability. In addition, a copper (Cu) alloy having a predetermined level of rigidity while having excellent electrical characteristics may generally be used as a material.

Thereafter, as shown in FIG. 9, a reflow is performed to melt the solder paste 19, thereby bonding the connection pad 13 to the lead pin 20. In this case, when the reflow is performed, the gold (Au) layers 17 and 25 of the surface treatment layer formed on the connection pad 13 and the lead pin 20 are diffused to the solder paste 19 so that they are not exposed and a very thin intermetallic compound (IMC) layer at several nm or less may be formed between the nickel layers 15 and 23 and the solder paste 19. Further, when the reflow is performed, a flux 19a is generated from the solder paste 19. As a result, a deflux is performed to remove the flux 19a as shown in FIG. 10.

The prior art uses the solder paste to bond the lead pin to the connection pad, such that there is a problem in moving the lead pin during the reflow. In addition, as the wiring density of the printed circuit board is increased, a lead pin mounting technology corresponding to a fine pin (a diameter of a pin is increasingly small) and a fine pin pitch (a distance between pins is shortened) is urgently needed.

### SUMMARY OF THE INVENTION

The present invention has been made in an effort to provide a printed circuit board capable of reducing the number of manufacturing processes, preventing a pin from being moved, and forming a fine pin pitch, and a method for manufacturing the same.

According to a preferred embodiment of the present invention, there is provided a printed circuit board, including: a base substrate having a connection pad; a lead pin bonded to the connection pad; and a surface treatment layer formed at the exposed portions of the connection pad and the lead pin.

The lead pin may be configured of a shaft portion and may be formed in an l-letter shape.

The surface treatment layer may be formed by an electroless nickel immersion gold (ENIG) method or an electroless nickel immersion palladium immersion gold (ENIPIG) method.

According to another preferred embodiment of the present invention, there is provided a method for manufacturing a printed circuit board, including: preparing a base substrate having a connection pad; bonding a lead pin to the connection pad; and forming a surface treatment layer on the exposed portions of the connection pad and the lead pin.

The lead pin may be configured of a shaft portion and may be formed in an l-letter shape.

The bonding the lead pin to the connection pad may be performed by welding.

The welding may be performed by any one of a diffusion welding method, a point welding method, a butt welding method, an ultrasonic welding method, a cold welding method, an explosion welding method, a friction welding method, an inertia welding method, an induction welding method, a thermite welding method, a flash welding method, an impact welding method, a seam welding method, and a projection welding method.

The surface treatment layer may be formed by an electroless nickel immersion gold (ENIG) method or an electroless nickel immersion palladium immersion gold method (ENIPIG).

### BRIEF DESCRIPTION OF THE DRAWINGS

FIG. 1 is a cross-sectional view schematically showing a structure of a printed circuit board according to a preferred embodiment of the present invention;

FIGS. 2 to 4 are schematic process flow charts for explaining a method for manufacturing a printed circuit board according a preferred embodiment of the present invention; and

FIGS. 5 to 10 are process flow charts schematically showing a method for manufacturing a printed circuit board according to the prior art.

### DESCRIPTION OF THE PREFERRED EMBODIMENTS

The above and other objects, features and advantages of the present invention will be more clearly understood from the following detailed description taken in conjunction with the accompanying drawings. In the specification, in adding reference numerals to components throughout the drawings, it is to be noted that like reference numerals designate like components even though components are shown in different drawings. Further, when it is determined that the detailed description of the known art related to the present invention may obscure the gist of the present invention, the detailed description thereof will be omitted. In the description, the terms “first”, “second” and so on are used to distinguish one element from another element, and the elements are not defined by the above terms.

Hereinafter, preferred embodiments of the present invention will be described in detail with reference to the accompanying drawings.

### Printed Circuit Board

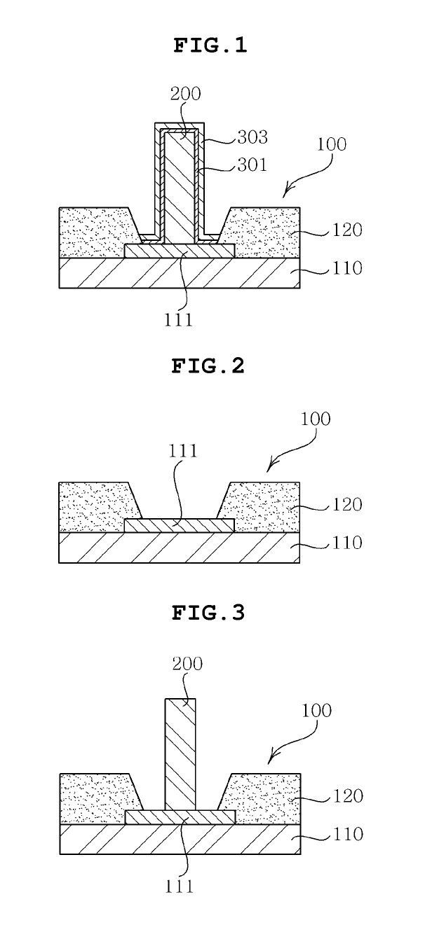

FIG. 1 is a cross-sectional view schematically showing a structure of a printed circuit board according to a preferred embodiment of the present invention.

As shown in FIG. 1, a printed circuit board 100 according to the present invention includes a base substrate 110, a lead pin 200, and surface treatment layers 301 and 303.

The base substrate 110 has a solder resist layer 120 having an opening through which the connection pad 111 is exposed.

The base substrate 110 is a printed circuit board on which a circuit configured of one or more layer including the connection pad 111 is formed on an insulating layer. FIG. 1 does not show a detailed inner circuit configuration for convenience of explanation. It can be apparently appreciated from those skilled in the art that as the substrate 110, a general printed circuit board in which a circuit configured of one or more layer is formed in an insulating layer is applied.

As the insulating layer, a resin insulating layer may be used. As the resin insulating layer, a thermosetting resin such as an epoxy resin, a thermoplastic resin such as polyimide, or a resin, in which a reinforcement material such as a glass fiber or an inorganic filler is impregnated, such as prepreg may be used. Further, as the resin insulating layer, the thermosetting resin and/or the photocurable resin, or the like, may be used; however, the preferred embodiment is not specifically limited thereto.

In addition, a material for a circuit including the connection pad 111 may be used without limitation if a conductive metal for a circuit may be used in the field of the circuit board. Generally, copper is used for the printed circuit board.

The solder resist layer 120 serves as a protective layer protecting a circuit at an outermost layer and is formed for electrical insulation and is provided with an opening to expose the connection pad 111 at the outermost layer. As known in those skilled in the art, the solder resist layer 120 may be configured of solder resist ink, a solder resist film, or an encapsulant, or the like, but is not specifically limited thereto.

It is preferable that the surface treatment layer is not formed on the exposed connection pad 111, unlike the prior art. Although this is described in the manufacturing method, the lead pin 200 and the connection pad 111 are not bonded to each other by using the solder paste, but are bonded by welding.

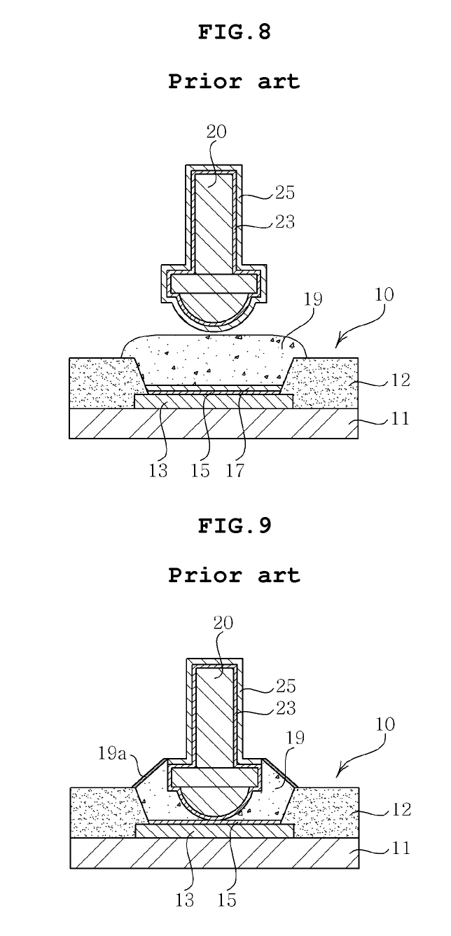

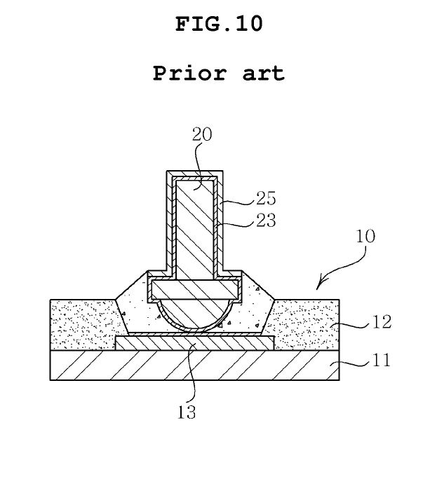

In this configuration, it is preferable that the lead pin 200 is configured of a shaft portion. That is, the lead pin 200 is configured of an l-letter shape. This is the greatest difference with the lead pin according to the prior art that is configured of a shaft portion and a head portion as shown in FIG. 8. However, the lead pin 200 of the present invention may also include the shaft portion and the head portion. In this case, it is preferable to manufacture the lead pin in an l-letter shape by making the diameter and shape of the shaft portion and the head portion equal.

Further, another difference between the lead pin 200 according to the present invention and the lead pin according to the prior art is that the surface treatment layer is not formed on the surface. As described in FIG. 8, the lead pin according to the prior art includes the surface treatment layer for preventing oxidation and corrosion on the surface of the lead pin, but in the present invention, the lead pin 200 does not include a separate surface treatment layer as shown in FIG. 3. Similar to the above description, the lead pin 200 and the connection pad 111 are not bonded to each other by reflowing the solder paste, but are bonded by welding.

As described above, the present invention manufactures the lead pin 200 in an l-letter shape, thereby making it possible to easily manufacture the lead pin 200 and does not include a process of forming a separate surface treatment layer on the surface of the lead pin 200, thereby making it possible to reduce the number of manufacturing processes.

Finally, the surface treatment layers 301 and 303 on the printed circuit board 100 according to the present invention are formed after bonding the lead pin 200 to the connection pad 111, which may be formed at the exposed portion of the connection pad 111 and the lead pin 200.

In this case, the surface treatment layer may be formed by an electroless nickel immersion gold (ENIG) method or an electroless nickel immersion palladium immersion gold (ENIPIG) method, but is not specifically limited thereto.

As described above, the bonding state of the lead pin 200 and the connection pad 111 may be stronger by bonding the lead pin 200 to the connection pad 111 and then, forming the surface treatment layer, thereby making it possible to prevent the surfaces of the connection pad 111 and the lead pin 200 from being oxidized and corroded.

### Method for Manufacturing Printed Circuit Board

FIGS. 2 to 4 are schematic process flow charts for explaining a method for manufacturing a printed circuit board according to a preferred embodiment of the present invention.

First, as shown in FIG. 2, a base substrate 110 having a connection pad 111 is prepared.

The base substrate 110 has a solder resist layer 120 having an opening through which the connection pad 111 is exposed.

In this configuration, it is preferable that the surface treatment layer is not formed on the connection pad 111. The reason is that the lead pin 200 and the connection pad 111 are bonded to the connection pad 111 by a welding method.

Next, as shown in FIG. 3, the connection pad 111 is bonded to the lead pin 200. In this configuration, it is preferable that the lead pin 200 is configured of only a shaft portion. For example, the lead pin maybe formed in an l-letter shape. However, it is also possible to manufacture the lead pin in an l-letter shape by dividing the shaft portion and the head portion and making the shape and diameter thereof equal.

In addition, similar to the connection pad 111, it is preferable that the surface treatment layer is not formed on the lead pin 200. The reason is that the connection pad 111 and the lead pin 200 are bonded to each other by the welding method to be described later, not the solder paste.

As described above, since the lead pin 200 is formed in a l-letter shape, it does not have a head portion having a diameter larger than that of a shaft portion, differently from the lead pin according to the prior art, such that the diameter of the connection pad 111 bonded thereto can be reduced accordingly. As a result, it is possible to maximally shorten the fine pin pitch, i.e., a distance between the pins.

The bonding between the lead pin 200 and the connection pad 111 may be performed by the welding method. As the welding method, there may be a diffusion welding method, a point welding method, a butt welding method, an ultrasonic welding method, a cold welding method, an explosion welding method, a friction welding method, an inertia welding method, an induction welding method, a thermite welding method, a flash welding method, an impact welding method, a seam welding method, or a projection welding method. In the present invention, the bonding between the lead pin 200 and the connection pad 111 may be performed by one method thereof.

That is, two metals that are not subjected to surface treatment, for example, the connection pad 111 and the lead pin 200 are disposed to be close to each other and then, are bonded to each other by the above-mentioned methods. As described above, the metal bonding method by welding is already known and therefore, the detailed description thereof will be omitted.

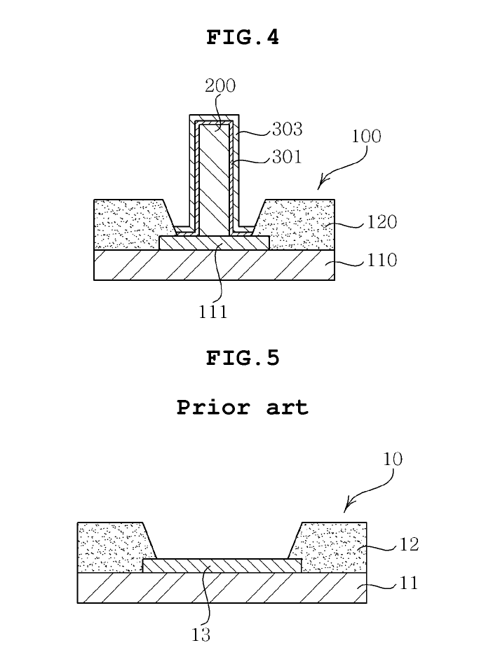

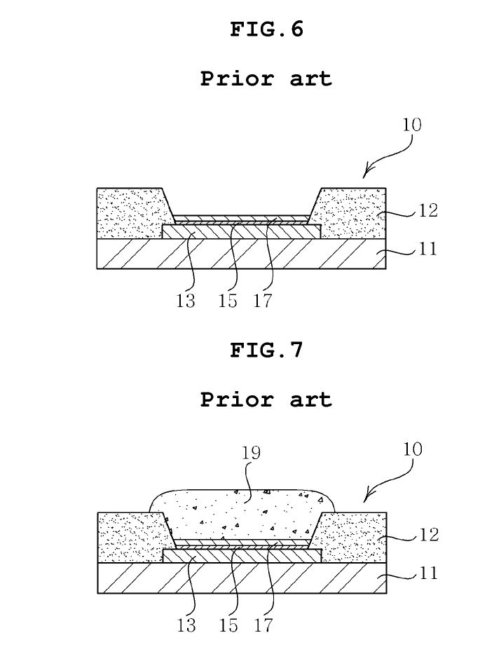

Thereafter, as shown in FIG. 4, the surface treatment layers 301 and 303 are formed in order to prevent the exposed portions of the connection pad 111 and the lead pin 200 bonded thereto from being oxidized and corroded. In this case, the inner surface treatment layer 301 of the surface treatment layer may be made of nickel and the outer surface treatment layer 303 may be made of gold Au, but is not specifically limited thereto.

In this case, the surface treatment layer may be formed by an electroless nickel immersion gold (ENIG) scheme or an electroless nickel immersion palladium immersion gold (ENIPIG) scheme, but is not specifically limited thereto.

As described above, the bonding state of the lead pin 200 and the connection pad 111 may be stronger by bonding the lead pin 200 to the connection pad 111 using the welding method and then, forming the surface treatment layers 301 and 303 on the exposed outer surface, thereby making it possible to prevent the exposed surfaces of the connection pad 111 and the lead pin 200 from being oxidized and corroded.

As set forth above, the present invention can form the lead pin in a shaft shape, i.e., an l-letter shape, thereby making it possible to easily manufacture the lead pin and can reduce the diameter of the connection pad corresponding to the head portion removed, thereby making it possible to form the fine pin pitch.

Further, the present invention does not form the surface treatment layer on the lead pin during the manufacture of the lead pin, thereby making it possible to reduce the number of manufacturing processes of the lead pin and saving manufacturing costs of the lead pin accordingly.

In addition, the present invention does not bond the lead pin to the connection pad without being soldered, thereby making it possible to solve the problems of the solder climb when the solder climbs to the shaft portion and the lead pin movement generated during the reflow process.

Although the preferred embodiments of the present invention have been disclosed for illustrative purposes, they are for specifically explaining the present invention and thus a printed circuit board and a method for manufacturing the same according to the present invention are not limited thereto, but those skilled in the art will appreciate that various modifications, additions and substitutions are possible, without departing from the scope and spirit of the invention as disclosed in the accompanying claims.

Accordingly, such modifications, additions and substitutions should also be understood to fall within the scope of the present invention.

What is claimed is:

1. A printed circuit board, comprising:
a base substrate having a connection pad;
a lead pin bonded to the connection pad; and
a surface treatment layer formed at the exposed portions of the connection pad and the lead pin.

2. The printed circuit board as set forth in claim 1, wherein the lead pin is configured of a shaft portion.

3. The printed circuit board as set forth in claim 2, wherein the lead pin is formed in an l-letter shape.

4. The printed circuit board as set forth in claim 1, wherein the surface treatment layer is formed by an electroless nickel immersion gold (ENIG) method or an electroless nickel immersion palladium immersion gold (ENIPIG) method.

5. A method for manufacturing a printed circuit board, comprising:
preparing a base substrate having a connection pad;
bonding a lead pin to the connection pad; and
forming a surface treatment layer on the exposed portions of the connection pad and the lead pin.

6. The method for manufacturing a printed circuit board as set forth in claim 5, wherein the lead pin is configured of a shaft portion.

7. The method for manufacturing a printed circuit board as set forth in claim 6, wherein the lead pin is formed in an l-letter shape.

8. The method for manufacturing a printed circuit board as set forth in claim 5, wherein the bonding the lead pin to the connection pad is performed by a welding.

9. The method for manufacturing a printed circuit board as set forth in claim 8, wherein welding is performed by any one of a diffusion welding method, a point welding method, a butt welding method, an ultrasonic welding method, a cold welding method, an explosion welding method, a friction welding method, an inertia welding method, an induction welding method, a thermite welding method, a flash welding method, an impact welding method, a seam welding method, and a projection welding method.

10. The method for manufacturing a printed circuit board as set forth in claim 5, wherein the surface treatment layer is formed by an electroless nickel immersion gold (ENIG) method or an electroless nickel immersion palladium immersion gold method (ENIPIG).
